(19) United States
(12) Patent Application Publication
(10) Pub. No.: US 2023/0018491 A1
(43) Pub. Date: Jan. 19, 2023

(54) THERMOSETTING RESIN COMPOSITION, RESIN SHEET, AND METAL BASE SUBSTRATE

(71) Applicant: SUMITOMO BAKELITE CO., LTD., Shinagawa-ku, Tokyo (JP)

(72) Inventors: Tomomasa Kashino, Tokyo (JP); Tadasuke Endo, Tokyo (JP); Akiyoshi Oba, Tokyo (JP)

(21) Appl. No.: 17/781,734

(22) PCT Filed: Dec. 9, 2020
(86) PCT No.: PCT/JP2020/045827

§ 371 Date: Jun. 2, 2022

(30) Foreign Application Priority Data
Dec. 9, 2019 (JP) 2019-222223

(51) Int. Cl. C08G 59/24; C08K 5/5435; C08K 3/38; H01L 23/373

(52) U.S. Cl. CPC C08G 59/245; C08K 5/5435; C08K 3/38; H01L 23/3737; C08G 2650/56; C08K 2003/385; C08K 2201/001

(57) ABSTRACT

A thermosetting resin composition, which constitutes at least a part of a heat-dissipating insulating member interposed between a heat-generating body and a heat-dissipating body, includes (A) an epoxy resin, (B) a thermosetting resin (excluding epoxy resin (A)), (C) a phenoxy resin having a mesogenic structure in the molecule, (D) thermally conductive particles, and (E) an organosiloxane compound.

### TECHNICAL FIELD

The present invention relates to a thermosetting resin composition, a resin sheet made of the composition, and a metal base substrate containing the resin sheet.

### BACKGROUND ART

Heat dissipation is required for insulating materials that constitute electrical and electronic equipment. Various developments have been made on the heat dissipation of insulating materials.

As this kind of technique, for example, the technique disclosed in Patent Document 1 is known. Patent Document 1 discloses a thermosetting resin composition using a bisphenol A type epoxy resin as a thermosetting resin and scaly or spherical boron nitride particles as thermally conductive particles.

### RELATED DOCUMENT

### Patent Document

[Patent Document 1] Japanese Unexamined Patent Application Publication No. 2015-193504

### SUMMARY OF THE INVENTION

### Technical Problem

However, in the technique in the related art disclosed in Patent Document 1, there was a case where a moisture absorption rate is high and insulation durability is lowered. It has been well known that the adhesion properties are not improved even if a silane coupling agent is added to thermally conductive particles such as boron nitride particles.

### Solution to Problem

As a result of finding and examining that moisture absorption in a resin or at an interface between the resin and thermally conductive particles affects the insulation durability, the present inventors have found that by combining the thermally conductive particles and an organosiloxane compound such as a silane coupling agent, the moisture absorption rate is lowered, and the insulation durability is improved.

According to the present invention, there is provided a thermosetting resin composition constituting at least a part of a heat-dissipating insulating member interposed between a heat-generating body and a heat-dissipating body, the thermosetting resin composition including:

(A) an epoxy resin;

(B) a thermosetting resin (excluding epoxy resin (A));

(C) a phenoxy resin containing a mesogenic structure in a molecule;

(D) thermally conductive particles; and

(E) an organosiloxane compound.

According to the present invention, there is provided a resin sheet made of the thermosetting resin composition.

In addition, according to the present invention, there is provided a metal base substrate including a metal substrate, an insulating layer obtained by curing the resin sheet, and a metal layer in this order.

### Advantageous Effects of Invention

According to the present invention, it is possible to provide a thermosetting resin composition, having a low moisture absorption rate and excellent insulation durability, and from which a resin sheet having excellent thermal conductivity and insulation properties is obtained, a resin sheet made of the composition, and a metal base substrate including the resin sheet.

### BRIEF DESCRIPTION OF THE DRAWINGS

FIG. 1 is a schematic cross-sectional view showing a configuration of a metal base substrate according to the present embodiment.

FIG. 2 is a schematic cross-sectional view showing a configuration of a semiconductor device using the metal base substrate according to the present embodiment.

### DESCRIPTION OF EMBODIMENTS

Hereinafter, embodiments of the present invention will be described with reference to the drawings. In the drawings, the same reference numerals are applied to the same constituent elements and explanations thereof will not be repeated. In addition, “˜” represents “greater than or equal to” to “less than or equal to” unless otherwise specified.

A thermosetting resin composition of the present embodiment constitutes at least a part of a heat-dissipating insulating member interposed between a heat-generating body and a heat-dissipating body, and includes (A) an epoxy resin, (B) a thermosetting resin (excluding the epoxy resin (A)), (C) a phenoxy resin containing a mesogenic structure in a molecule, (D) thermally conductive particles, and (E) an organosiloxane compound.

Examples of the heat-generating body include a semiconductor element, an LED element, a semiconductor element, a substrate on which an LED element is mounted, a Central Processing Unit (CPU), a power semiconductor, a lithium ion battery, a fuel cell, and the like.

Examples of the heat-dissipating body include a heat sink, a heat spreader, a heat-dissipating (cooling) fin, and the like.

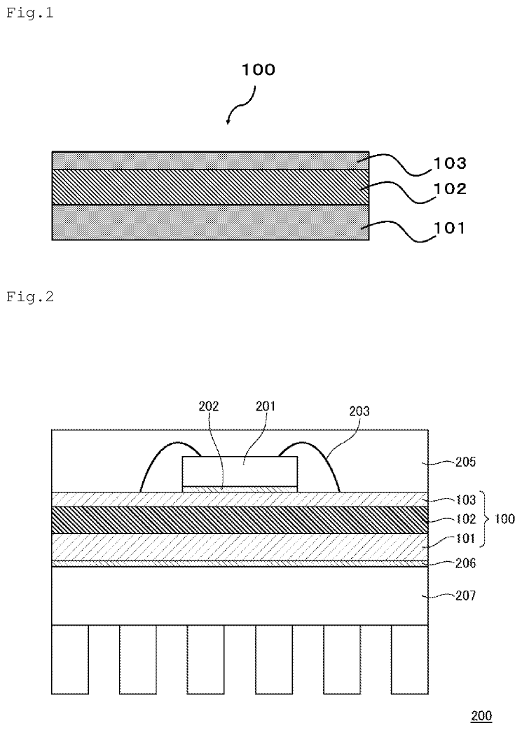

The heat-dissipating insulating member may be partially made of the thermosetting resin composition of the present embodiment, and specific examples thereof include a heat-dissipating sheet obtained by curing the thermosetting resin composition and a laminate in which the heat-dissipating sheet and a substrate are laminated (for example, a metal base substrate 100 in FIG. 1). The substrate is not particularly limited as long as the substrate is a heat-dissipating metal substrate, examples thereof include a copper substrate, a copper alloy substrate, an aluminum substrate, and an aluminum alloy substrate, and a copper substrate or an aluminum substrate is preferable and a copper substrate is more preferable. Using a copper substrate or an aluminum substrate makes it possible to make the heat dissipation of the heat-dissipating insulating member good.

The heat-dissipating insulating member is partially made of the thermosetting resin composition of the present embodiment, and thermal conductivity is preferably 12 W/m·K or more, and more preferably 15 W/m·K or more.

The heat-dissipating insulating member and the heat-dissipating body may be formed on one surface of the heat-generating body, or may be formed on both surfaces thereof. In addition, various base materials or layers maybe provided between the heat-generating body and the heat-dissipating insulating member, or between the heat-dissipating insulating member and the heat-dissipating body within a range that does not affect the heat-dissipating properties.

In the present embodiment, the heat-generating body, the heat-dissipating insulating member, and the heat-dissipating body can obtain a laminated structure body by appropriately combining the above-described ones. The laminated structure body can be used for various usages that require heat-dissipating insulation properties, and can be used for various usages such as semiconductor devices, smartphones, LED bulbs/lights, power modules, lithium-ion batteries, fuel cells, wireless base stations, and uninterruptible power supplies.

Hereinafter, components contained in the thermosetting resin composition of the present embodiment will be described.

### Epoxy Resin (A)

As the epoxy resin (A), known ones can be used as long as the effects of the present invention are exhibited. Examples of the epoxy resin include glycidyl ethers such as bisphenol A type, F type, S type, and AD type, hydrogenated bisphenol A type glycidyl ethers, phenol novolac type glycidyl ethers, cresol novolac type glycidyl ethers, bisphenol A type novolac type glycidyl ethers, naphthalene type glycidyl ethers, biphenol type glycidyl ethers, dihydroxypentadiene type glycidyl ethers, triphenylmethane type epoxy resins, phenol novolac type epoxy resins, cresol novolac type epoxy resins, hydroquinone type glycidyl ethers, and the like, and at least one type can be used.

The epoxy resin (A) preferably contains at least one selected from naphthalene type glycidyl ether, biphenol type glycidyl ether, dihydroxypentadiene type glycidyl ether, and hydroquinone type glycidyl ether, from a viewpoint of the effect of the present invention.

The epoxy resin (A) can preferably include an epoxy resin containing a mesogenic skeleton. Due to this, it is possible to further improve the thermal conductivity (heat dissipation) during curing.

It is considered that a higher-order structure (liquid crystal phase or crystalline phase) is formed by the mesogenic skeleton when the epoxy resin including the mesogenic skeleton is cured. It is considered that the thermal conductivity (heat dissipation) is further improved by the transmission of heat through the higher-order structure. Also, it is possible to examine the presence of the higher-order structure in the cured product by observation using a polarized light microscope.

Examples of the mesogenic skeleton may include any skeleton which facilitates the expression of liquid crystallinity and crystallinity through the action of intermolecular interactions. The mesogenic skeleton preferably includes a conjugated structure. Specific examples of the mesogenic skeleton include a biphenyl skeleton, a phenylbenzoate skeleton, an azobenzene skeleton, a stilbene skeleton, a naphthalene skeleton, an anthracene skeleton, a chalcone skeleton, a phenanthrene skeleton, and the like.

The epoxy resin (A) particularly preferably includes a condensed polycyclic aromatic hydrocarbon skeleton, and especially preferably includes a naphthalene skeleton.

For example, with a biphenyl skeleton (—C₆H₄—C₆H₄—), there is a possibility that, at high temperatures, thermal motion may “rotate” the carbon-carbon single bond portion at the center of the left-hand structure and decrease the liquid crystallinity. Similarly, with a phenylbenzoate skeleton (—C₆H₄—COO—C₆H₄—), there is a possibility that the ester bond may rotate at high temperatures. However, for condensed polycyclic aromatic hydrocarbon skeletons such as a naphthalene skeleton, in principle, there is no decrease in liquid crystallinity due to such rotation. In other words, including a condensed polycyclic aromatic hydrocarbon skeleton in the epoxy resin makes it easier to further improve the heat dissipation in high temperature environments.

In addition, using a naphthalene skeleton in particular as a polycyclic aromatic hydrocarbon skeleton also makes it possible to suppress the epoxy resin from becoming excessively rigid while obtaining the above advantages. This is because the naphthalene skeleton is comparatively small as a mesogenic skeleton. The fact that the epoxy resin is not excessively rigid is preferable in terms of the suppression of cracks and the like due to easy alleviation of stress during the curing of the thermosetting resin composition of the present embodiment.

The epoxy resin (A) preferably includes a bifunctional or higher epoxy resin. In other words, two or more epoxy groups are preferably included in one molecule of the epoxy resin. The number of functional groups of the epoxy resin is preferably 2 to 6, and more preferably 2 to 4.

From a viewpoint of the effect of the present invention, the epoxy resin (A) in the present embodiment preferably contains 1 or 2 or more selected from the compounds represented by the following formulas.

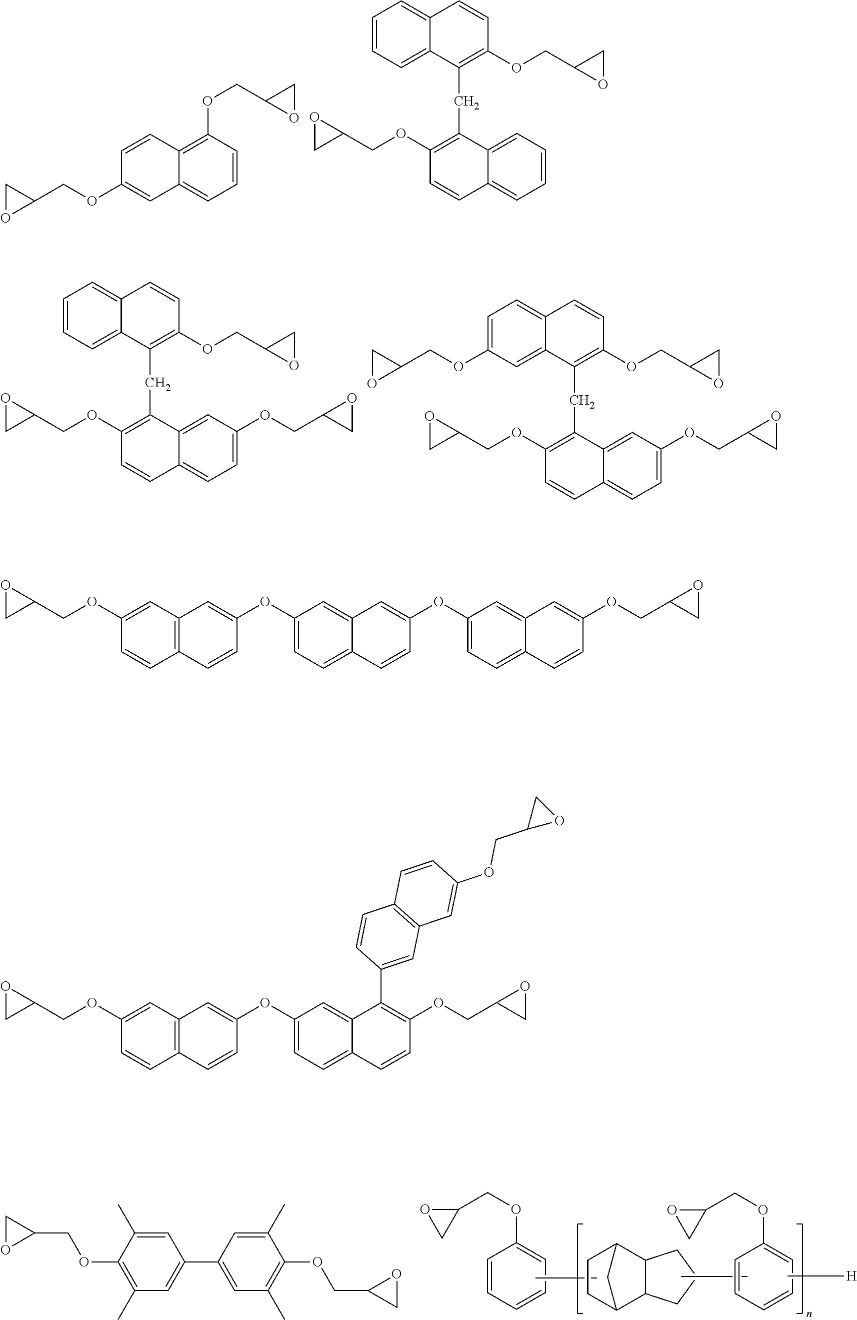

The epoxy equivalent of the epoxy resin (A) is, for example, 100 to 200 g/eq, preferably 105 to 190 g/eq, more preferably 110 to 180 g/eq. Using an epoxy resin having an appropriate epoxy equivalent makes it possible to control the curability, optimize the physical properties of the cured product, and the like.

As one aspect, the epoxy resin preferably further includes another epoxy resin which is liquid or semi-solid at room temperature (23° C.). Specifically, a part or all of the epoxy resin is preferably in liquid or semi-solid form at 23° C.

The use of a liquid or semi-solid epoxy resin is preferable in terms of ease of forming a cured product with a desired shape and the like.

The thermosetting resin composition of the present embodiment may include only one epoxy resin or may include two or more epoxy resins.

The epoxy resin (A) is, for example, 5% by mass to 40% by mass, preferably 7% by mass to 35% by mass, and more preferably 10% by mass to 30% by mass, based on the resin component (100% by mass) of the thermosetting resin composition containing no thermally conductive particles (D). Due to this, sufficient curability can be ensured, and a resin sheet having higher thermal conductivity and excellent insulation properties can be obtained.

The thermosetting resin composition containing no thermally conductive particles (D) is made of a resin component other than the thermally conductive particles (D), and the resin components include an epoxy resin (A) and a thermosetting resin (B).

### Thermosetting Resin (B)

The thermosetting resin composition of the present embodiment contains a thermosetting resin (B). The thermosetting resin (B) does not contain the epoxy resin (A).

Examples of the thermosetting resin (B) include a thermosetting compound containing a mesogenic structure (mesogenic skeleton) in the molecule and a thermosetting compound containing no mesogenic structure in the molecule.

Examples of the thermosetting resin (B) include a cyanate resin, a maleimide resin, a phenolic resin, a benzoxazine resin, a polyimide resin, an unsaturated polyester resin, a melamine resin, a silicone resin, an acrylic resin, and derivatives of these phenolic derivatives, and at least one can be included.

In the present embodiment, the thermosetting resin (B) preferably contains at least one selected from a cyanate resin, a bismaleimide resin, a phenolic resin, and a benzoxazine resin, and more preferably contains at least a cyanate resin.

As these thermosetting resins, monomers, oligomers, and polymers having two or more reactive functional groups in one molecule can be used in general, and the molecular weight or molecular structure thereof is not particularly limited.

(Cyanate Resin)

As the cyanate resin, known ones can be used as long as the effects of the present invention are exhibited. Examples of the cyanate resin include one or two or more selected from a novolac type cyanate resin; a bisphenol type cyanate resin such as a bisphenol A type cyanate resin, a bisphenol E type cyanate resin, a tetramethyl bisphenol F type cyanate resin; a naphthol aralkyl type cyanate resin obtained by reaction of naphthol aralkyl type phenolic resin and halogenated cyan; a dicyclopentadiene type cyanate resin; and a phenolic aralkyl type cyanate resin having a biphenylene skeleton. Among these, from a viewpoint of the effect of the present invention, it is more preferable to include at least one of the novolac type cyanate resin and the naphthol aralkyl type cyanate resin, and it is particularly preferable to include the novolac type cyanate resin.

As the novolac type cyanate resin, for example, one represented by the following General Formula (I) can be used.

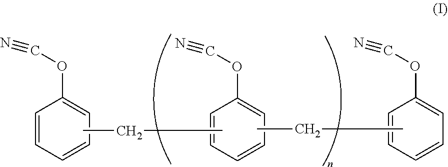

An average repeating unit n of the novolac type cyanate resin represented by General Formula (I) is an optional integer. The average repeating unit n is not particularly limited, but is preferably 1 or more, and more preferably 2 or more. When the average repeating unit n is at least the lower limit value, it is possible to improve the heat resistance of the novolac type cyanate resin, and to further suppress the desorption and volatilization of the low-weight body during heating. In addition, the average repeating unit n is not particularly limited, but is preferably 10 or less, and more preferably 7 or less. When n is not more than the upper limit value, it is possible to suppress the increase in melt viscosity and improve the moldability of the resin sheet.

In addition, as the cyanate resin, a naphthol aralkyl type cyanate resin represented by the following General Formula (II) is also suitably used. The naphthol aralkyl type cyanate resin represented by the following General Formula (II) is, for example, obtained by condensing naphthol aralkyl type phenolic resin and halogenated cyan obtained by reaction of naphthols such as α-naphthol or β-naphthol, and p-xylylene glycol, α, α′-dimethoxy-p-xylene, 1,4-di (2-hydroxy-2-propyl) benzene. The repeating unit n of General Formula (II) is preferably an integer of 10 or less. When the repeating unit n is 10 or less, a more uniform resin sheet can be obtained. In addition, intermolecular polymerization is unlikely to occur during synthesis, liquid separation property during washing with water is improved, and there is a tendency that a decrease in yield can be prevented.

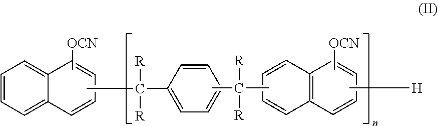

In General Formula (II), R independently represents a hydrogen atom or a methyl group, and n represents an integer of 1 or more and 10 or less.

The cyanate resin is, for example, 10% by mass to 70% by mass, preferably 15% by mass to 60% by mass, and more preferably 20% by mass to 50% by mass, based on the resin component (100% by mass) of the thermosetting resin composition containing no thermally conductive particles (D). Due to this, sufficient curability can be ensured, and a resin sheet having higher thermal conductivity and excellent insulation properties can be obtained.

(Maleimide Resin)

The maleimide resin is preferably, for example, a maleimide resin having at least two maleimide groups in the molecule.

Examples of the maleimide resin having at least two maleimide groups in the molecule include a resin having two maleimide groups in the molecule such as 4,4′-diphenylmethane bismaleimide, m-phenylene bismaleimide, p-phenylene bismaleimide, 2,2-bis[4-(4-maleimide phenoxy) phenyl]propane, bis-(3-ethyl-5-methyl-4-maleimide phenyl) methane, 4-methyl-1,3-phenylene bismaleimide, N, N′-ethylene dimaleimide, N, N′-hexamethylene dimaleimide, bis(4-maleimide phenyl)ether, bis(4-maleimide phenyl)sulfone, 3,3-dimethyl-5,5-diethyl-4,4-diphenylmethane bismaleimide, and bisphenol A diphenyl ether bismaleimide, a resin having three or more maleimide groups in the molecule such as a biphenyl aralkyl type maleimide and polyphenylmethane maleimide, and the like.

(Phenolic Resin)

Examples of the phenolic resin include novolac type phenolic resins such as phenolic novolac resin, cresol novolac resin, and bisphenol A novolac resin, and resol type phenolic resin, and the like. One among these may be used alone, or two or more may be used in combination.

Among the phenolic resins, phenolic novolac resin is preferable.

(Benzoxazine Resin)

Specific examples of the benzoxazine resin include o-cresol aniline type benzoxazine resin, m-cresol aniline type benzoxazine resin, p-cresol aniline type benzoxazine resin, phenol-aniline type benzoxazine resin, phenol-methylamine type benzoxazine resin, phenol-cyclohexylamine type benzoxazine resin, phenol-m-toluidine type benzoxazine resin, phenol-3,5-dimethylaniline type benzoxazine resin, bisphenol A-aniline type benzoxazine resin, bisphenol A-amine type benzoxazine resin, bisphenol F-aniline type benzoxazine resin, bisphenol S-aniline type benzoxazine resin, dihydroxydiphenyl sulfone-aniline type benzoxazine resin, dihydroxydiphenyl ether-aniline type benzoxazine resin, benzophenone type benzoxazine resin, biphenyl type benzoxazine resin, bisphenol AF-aniline type benzoxazine resin, bisphenol A-methylaniline type benzoxazine resin, phenol-diaminodiphenyl methane type benzoxazine resin, triphenylmethane type benzoxazine resin, phenolphthaline type benzoxazine resin, and the like.

From a viewpoint of the effect of the present invention, the content of the thermosetting resin (B) is, for example, preferably 0.1% by mass to 70% by mass, more preferably 0.5% by mass to 65% by mass, and even more preferably 1% by mass to 60% by mass, based on the resin component (100% by mass) of the thermosetting resin composition containing no thermally conductive particles (D).

### Phenoxy Resin (C)

The thermosetting resin composition of the present embodiment includes a phenoxy resin (C) containing a mesogenic structure in the molecule.

One example of a mesogenic structure-containing phenoxy resin is a resin which includes a structural unit derived from a phenolic compound and a structural unit derived from an epoxy compound in the molecule and which includes a compound having a mesogenic structure in at least one of these structural units.

In addition, another example of a mesogenic structure-containing phenoxy resin is a resin which includes, in the molecule, a structural unit derived from a mesogenic structure-containing phenolic compound.

An example of the mesogenic structure-containing phenoxy resin can be manufactured by a known technique, and it is possible to obtain a mesogenic structure-containing phenoxy resin by reacting a polyfunctional phenolic compound having two or more hydroxy groups in the molecule with a polyfunctional epoxy compound having two or more epoxy groups in the molecule.

That is, it is possible for the phenoxy resin to include a reaction compound of a polyfunctional phenolic compound and a polyfunctional epoxy compound. Either or both of these polyfunctional phenolic compounds and polyfunctional epoxy compounds have a mesogenic structure.

In addition, another example of the mesogenic structure-containing phenoxy resin can be manufactured by a known technique, and it is possible to obtain a mesogenic structure-containing phenoxy resin by the addition polymerization reaction of a mesogenic structure-containing phenolic compound having two or more phenolic groups in the molecule in epichlorohydrin.

That is, it is possible for the phenoxy resin to include the addition polymerization product of the mesogenic structure-containing phenolic compound.

It is possible to perform the manufacturing of the phenoxy resin without a solvent or in the presence of a reaction solvent. As a reaction solvent, it is possible to suitably use a non-protic organic solvent, for example, methyl ethyl ketone, dioxane, tetrahydrofuran, acetophenone, N-methylpyrrolidone, dimethyl sulfoxide, N,N-dimethylacetamide, sulfolane, cyclohexanone, and the like. It is possible to obtain a resin dissolved in a suitable solvent by performing solvent substitution or the like after the reaction. In addition, it is also possible to make the phenoxy resin obtained by the solvent reaction into a solid resin which does not include a solvent by a desolvation process using an evaporator or the like.

As reaction catalysts able to be used in the manufacturing of the phenoxy resin, polymerization catalysts known in the related art, for example, alkali metal hydroxides, tertiary amine compounds, quaternary ammonium compounds, tertiary phosphine compounds, quaternary phosphonium compounds, imidazole compounds, and the like, are suitably used.

The weight average molecular weight (Mw) of the phenoxy resin is usually 500 to 200,000. It is preferably 1,000 to 100,000, and more preferably 2,000 to 50,000. Mw is a value measured by gel permeation chromatography and converted using a standard polystyrene calibration curve.

In the present embodiment, the mesogenic structure has, for example, the structure represented by General Formula (1) or General Formula (2).

-A1-x-A2- (1)

-x-A1-x- (2)

In General Formula (1) and General Formula (2), A1 and A2 each independently represent an aromatic group, a fused aromatic group, an alicyclic group, or an alicyclic heterocyclic group, and x each independently represents a direct bond or a divalent bonding group selected from the group consisting of —O—, —C═C—, —C≡C—, —CO—, —CO—O—, —CO—NH—, —CH═N—, —CH═N—N═CH—, —N═N—, and —N(O)═N—.

Here, A1 and A2 are each independently preferably selected from a hydrocarbon group with a benzene ring having 6 to 12 carbon atoms, a hydrocarbon group with a naphthalene ring having 10 to 20 carbon atoms, a hydrocarbon group with a biphenyl structure having 12 to 24 carbon atoms, a hydrocarbon group with three or more benzene rings having 12 to 36 carbon atoms, a hydrocarbon group with a fused aromatic group having 12 to 36 carbon atoms, and an alicyclic heterocyclic group having 4 to 36 carbon atoms. A1 and A2 may be unsubstituted, or may be derivatives having substituents.

Specific examples of A1 and A2 in the mesogenic structure include phenylene, biphenylene, naphthylene, anthracenylene, cyclohexyl, pyridyl, pyrimidyl, thiophenylene, and the like. In addition, the above may be unsubstituted or may be derivatives having substituents such as aliphatic hydrocarbon groups, halogen groups, cyano groups, and nitro groups.

As the x corresponding to the bonding group (linking group) in the mesogenic structure, for example, a direct bond or a divalent substituent selected from the group consisting of —C═C—, —C≡C—, —CO——O—, —CO—NH—, —CH═N—, —CH═N—N═CH—, —N═N—, or —N(O)═N— is preferable.

Here, a direct bond means a single bond or that A1 and A2 in the mesogenic structure are linked to each other to form a ring structure. For example, a naphthalene structure may be included in the structure represented by General Formula (1).

In addition, as a polyfunctional phenolic compound, it is possible to use a mesogenic structure-containing compound represented by General Formula (A). These compounds maybe used alone or in a combination of two or more.

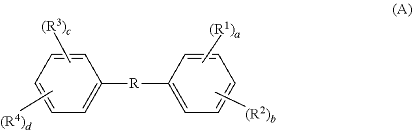

In General Formula (A), R¹ and R³ each independently represent a hydroxy group, R² and R⁴ each independently represent one selected from a hydrogen atom, a chain or cyclic alkyl group having 1 to 6 carbon atoms, a phenyl group, and a halogen atom, a and c each independently are an integer of 1 to 3, and b and d each independently are an integer of 0 to 2. However, a+b and c+d each are any one of 1 to 3. a+c may be 3 or more.

In addition, as the polyfunctional epoxy compound, for example, it is possible to use a mesogenic structure-containing compound represented by General Formula (B). These compounds may be used alone or in a combination of two or more.

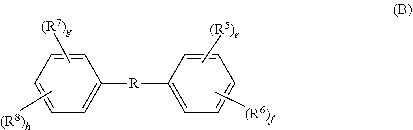

In General Formula (B) , R⁵ and R⁷ each independently represent a glycidyl ether group, R⁶ and R⁸ each independently represent one selected from a hydrogen atom, a chain or cyclic alkyl group having 1 to 6 carbon atoms, a phenyl group, and a halogen atom, e and g each are an integer of 1 to 3, and f and h each are an integer of 0 to 2. However, e+f and g+h each are any one of 1 to 3.

In addition, R in General Formula (A) and General Formula (B) represent -A1-x-A2-, -x-A1-x-, or -x- as described above, respectively. The two benzene rings in General Formula (A) may be linked to each other to form a condensed ring.

Specific examples of the R², R⁴, R⁶, and R⁸ include a hydrogen atom, a methyl group, an ethyl group, a propyl group, a butyl group, a chlorine atom, a bromine atom, and the like, respectively, and among these, in particular, a hydrogen atom or a methyl group are preferable.

As the polyfunctional epoxy compound containing a mesogenic structure, for example, addition polymerization products of the compound represented by General Formula (B) may be used. These compounds may be used alone or in a combination of two or more.

As the polyfunctional phenolic compound and the polyfunctional epoxy compound, a polyfunctional phenolic compound having three or more hydroxy groups in the molecule and a polyfunctional epoxy compound having two or more epoxy groups in the molecule may be used.

That is, it is possible for the phenoxy resin to include a branched reaction compound of a polyfunctional phenolic compound having three or more hydroxy groups in the molecule and a polyfunctional epoxy compound having two or more epoxy groups in the molecule.

It is possible for the polyfunctional phenolic compound having three or more hydroxy groups in the molecule to include, for example, polyphenols or polyphenolic derivatives.

A polyphenol is a compound which contains three or more phenolic hydroxy groups in one molecule. In addition, the polyphenol is preferably provided with the mesogenic structure described above in the molecule. For example, as the mesogenic structure, it is possible to use a biphenyl skeleton, a phenylbenzoate skeleton, an azobenzene skeleton, a stilbene skeleton, or the like.

Polyphenolic derivatives include compounds which are changed to other substituents at substitutable positions in the compound, with respect to polyphenolic compounds having three or more phenolic hydroxy groups and a mesogenic structure.

In the present embodiment, it is possible to obtain the branched reaction compound described above by using one or two or more of the polyfunctional phenolic compounds described above, including a polyfunctional phenolic compound having at least three or more hydroxy groups in the molecule, and one or two or more of the polyfunctional epoxy resins described above.

For example, a combination of a trifunctional phenolic compound and a bifunctional epoxy compound or a combination of a trifunctional phenolic compound, a bifunctional phenolic compound, and a bifunctional epoxy compound may be used.

As a trifunctional phenolic compound, for example, it is possible to use resveratrol, represented by the following chemical formula.

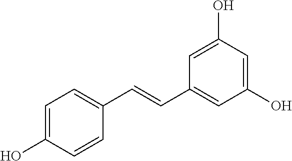 [SMILES: Oc1ccc(/C=C/c2cc(O)cc(O)c2)cc1]

As the bifunctional phenolic compound, for example, it is possible to use one in which the hydroxy groups of R¹ and R³ described above are bonded to the para-position of the respective benzene rings.

In addition, as the bifunctional epoxy compound, for example, it is possible to use one in which the glycidyl ether groups of R⁵ and R⁷ described above are bonded to the para-position of the respective benzene rings.

In addition, in a case where the bifunctional phenolic compound is provided with a naphthalene ring as a condensed ring, it is possible to use a compound in which the hydroxy groups of R¹ and R³ are bonded to any one of position 1 and position 4, position 1 and position 5, position 1 and position 6, position 2 and position 3, position 2 and position 6, or position 2 and position 7 of the naphthalene ring. In addition, in a case where the bifunctional epoxy compound described above is provided with a naphthalene ring as a condensed ring, it is possible to use a compound in which the glycidyl ether groups of R⁵ and R⁷ described above are bonded to any one of position 1 and position 4, position 1 and position 5, position 1 and position 6, position 2 and position 3, position 2 and position 6, or position 2 and position 7 of the naphthalene ring.

It is possible to obtain a branched reaction compound (branched phenoxy resin) by combining a trifunctional phenolic compound and a bifunctional epoxy compound as described above, or by combining a trifunctional phenolic compound, a bifunctional phenolic compound, and a bifunctional epoxy compound.

On the other hand, among the polyfunctional phenolic compounds and the polyfunctional epoxy compounds described above, bifunctional phenolic compounds and bifunctional epoxy compounds may be used. These compounds may be used alone or in a combination of two or more.

In other words, it is possible for the phenoxy resin to include a linear reaction compound of a bifunctional phenolic compound having two hydroxy groups in the molecule and a bifunctional epoxy compound having two epoxy groups in the molecule.

As the bifunctional phenolic compound, it is possible to use a compound in which the hydroxy groups of R¹ and R³ are bonded to the para-position of the respective benzene rings. In addition, as the bifunctional epoxy compound, for example, it is possible to use one in which the glycidyl ether groups of R⁵ and R⁷ described above are bonded to the para-position of the respective benzene rings.

In addition, in a case where the bifunctional phenolic compound is provided with a naphthalene ring as a condensed ring, it is possible to use a compound in which the hydroxy groups of R¹ and R³ are bonded to any one of position 1 and position 4, position 1 and position 5, position 1 and position 6, position 2 and position 3, position 2 and position 6, or position 2 and position 7 of the naphthalene ring. In addition, in a case where the bifunctional epoxy compound described above is provided with a naphthalene ring as a condensed ring, it is possible to use a compound in which the glycidyl ether groups of R⁵ and R⁷ described above are bonded to any one of position 1 and position 4, position 1 and position 5, position 1 and position 6, position 2 and position 3, position 2 and position 6, or position 2 and position 7 of the naphthalene ring.

Using such a bifunctional phenolic compound and a bifunctional epoxy compound together makes it possible to obtain a linear reaction compound (linear phenoxy resin).

It is possible for the branched phenoxy resins and the linear phenoxy resins to have epoxy groups or hydroxy groups at the end of the molecule and epoxy groups or hydroxy groups inside the molecule. Having epoxy groups at the end or inside the molecule makes it possible to form cross-linking reactions, and thus it is possible to increase heat resistance.

In addition, having a linear structural unit which is rigid and electron conjugated makes it possible to improve the heat-dissipating properties.

The phenoxy resin (C) is, for example, 5% by mass to 60% by mass, preferably 10% by mass to 50% by mass, and more preferably 15% by mass to 40% by mass, with respect to the resin component (100% by mass) of the thermosetting resin composition containing no thermally conductive particles (D). With this, it is possible to obtain a resin sheet having higher thermal conductivity and excellent insulation properties.

### Thermally Conductive Particles (D)

The thermosetting resin composition of the present embodiment includes thermally conductive particles (D).

The thermally conductive particles (D) can include, for example, high thermally conductive inorganic particles having a thermal conductivity of 20 W/m·K or more. As the highly thermally conductive inorganic particles, for example, at least one or more selected from silica, alumina, aluminum nitride, boron nitride, silicon nitride, silicon carbide, and magnesium oxide can be included. These compounds may be used alone or in a combination of two or more.

It is possible for boron nitride to include, for example, monodispersed particles or aggregated particles of scaly boron nitride, or mixtures thereof. The scaly boron nitride may be granulated in the form of granules. Using aggregated particles of scaly boron nitride further improves the thermal conductivity. The aggregated particles may be sintered particles or non-sintered particles.

The thermally conductive particles (D) (100% by mass) can contain the boron nitride in an amount of 60% by mass or more, preferably 65% by mass or more, and more preferably 70% by mass or more. An upper limit value is not particularly limited, but can be 100% by mass or less, preferably 95% by mass or less, and more preferably 90% by mass or less.

Although it is well known that the adhesion does not improve even if a silane coupling agent is added to the boron nitride particles, by using the organosiloxane compound (E) of the present embodiment, it is possible to obtain a resin sheet having a low moisture absorption rate and excellent insulation durability, and having excellent thermal conductivity and insulation properties, even in a case where the thermally conductive particles (D) contain the boron nitride particles in the above amount.

The content of the thermally conductive particles (D) is 100% by mass to 400% by mass, preferably 150% by mass to 350% by mass, and more preferably 200% by mass to 330% by mass, with respect to the resin component (100% by mass) of the thermosetting resin composition. By setting the value to the lower limit value or more, it is possible to improve the thermal conductivity. By setting the value to the upper limit value or less, it is possible to suppress a decrease in processability.

### Organosiloxane Compound (E)

The thermosetting resin composition of the present embodiment contains an organosiloxane compound (E).

Since it is well known that the adhesion does not improve even if a silane coupling agent is added to thermally conductive particles such as boron nitride particles, the effect of addition has not been examined so far. This time, when the organosiloxane compound (E) was added to the thermally conductive particles (D), it was clarified that a resin sheet having a low moisture absorption rate and excellent insulation durability and excellent thermal conductivity and insulation properties could be obtained, thereby completing the present invention. Although this mechanism is not clear, it is assumed that due to the addition of the organosiloxane compound, an effect of a polar functional group, which slightly presents in an end surface of the thermally conductive particles or the in-plane lattice defects and deteriorates the compatibility of the resin and the thermally conductive particles, is excluded and compatibility or hydrophobicity at an interface between the resin and the thermally conductive particles is improved, and as a result, the thermal resistance at the interface is lowered and the moisture absorption properties are further lowered.

The organosiloxane compound (E) is an aliphatic hydrocarbon compound having a Si—OQ bond (Q is an alkyl group) at one end of the molecular chain. The organosiloxane compound (E) more preferably includes at least one group selected from an epoxy group, a glycidyl ether group, an amino group, an isocyanate group, a phenyl group, a carboxyl group, a hydroxyl group, an alkyl group, a vinyl group, a mercapto group, and an azasilacyclopentyl group at the other end. With this, it is possible to obtain a resin sheet having a lower moisture absorption rate and a more excellent insulation durability.

The organosiloxane compound (E) can include a compound represented by General Formula (1).

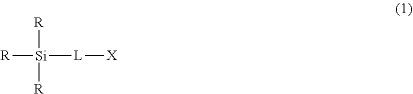

In General Formula (1), R each independently represents an alkoxy group having 1 to 3 carbon atoms or an alkyl group having 1 to 3 carbon atoms, and at least two Rs are alkoxy groups having 1 to 3 carbon atoms. All of Rs are preferably an alkoxy group having 1 to 3 carbon atoms, and more preferably an alkoxy group having 1 to 2 carbon atoms.

L represents a linear or branched alkylene group having 2 to 12 carbon atoms.

X represents an epoxy group, a glycidyl ether group, an amino group, an isocyanate group, a phenyl group, a carboxyl group, a hydroxyl group, an alkyl group, a vinyl group, or a mercapto group. From a viewpoint of the effect of the present invention, X is preferably an epoxy group, a glycidyl ether group, an amino group, an isocyanate group, an alkyl group having 1 to 3 carbon atoms, a phenyl group and a mercapto group, and from a viewpoint of the pot life of the thermosetting resin composition, an epoxy group, a phenyl group, a glycidyl ether group, a phenyl group and a methyl group are more preferable.

Examples of the compound represented by General Formula (1) include 3-aminopropyltriethoxysilane, 3-aminopropyltrimethoxysilane, 3-glycidoxypropyltriethoxysilane, 3-glycidoxypropyltrimethoxysilane, 3-mercaptopropyltriethoxysilane, 3-mercaptopropyltrimethoxysilane, 3-isocyanatepropyltriethoxysilane, glycidoxyoctyltriethoxysilane, glycidoxyoctyltrimethoxysilane, decyltriethoxysilane, phenyltriethoxysilane, phenyl trimethoxysilane, and the like.

The thermosetting resin composition of the present embodiment can contain the organosiloxane compound (E) in an amount of 0.01 to 0.5 parts by mass, preferably 0.02 to 0.3 parts by mass, and more preferably 0.03 to 0.2 parts by mass, with respect to 100 parts by mass of the thermally conductive particles (D). With this, it is possible to obtain a resin sheet having a lower moisture absorption rate and a more excellent insulation durability.

### Curing Accelerator (F)

The thermosetting resin composition of the present embodiment can contain a curing accelerator (F), depending on the necessity.

The type and blending amount of the curing accelerator (F) are not particularly limited. An appropriate curing accelerator may be selected from the viewpoints of reaction rate, reaction temperature, storability, and the like.

Examples of curing accelerators (F) include imidazoles, organophosphorus compounds, tertiary amines, phenolic compounds, organic acids, and the like. These compounds may be used alone or in a combination of two or more. Among these, from the viewpoint of heat resistance, nitrogen atom-containing compounds such as imidazoles are preferably used.

Examples of the imidazoles include 2-methylimidazole, 2-ethyl-4-methylimidazole, 2-phenyl-4-methylimidazole, 2,4-diethylimidazole, 2-phenyl-4-methyl-5-hydroxyimidazole, 2-phenyl-4,5-dihydroxymethylimidazole, 1-cyanoethyl-2-phenylimidazole, 1-cyanoethyl-2-phenylimidazolium trimellitate, and the like.

Examples of the tertiary amines include triethylamine, tributylamine, 1,4-diazabicyclo[2.2.2]octane, 1,8-diazabicyclo(5,4,0)undecene-7, and the like.

Examples of the phenolic compounds include phenolic resin, bisphenol A, nonylphenol, 2,2-bis(3-methyl-4-hydroxyphenyl)propane, allylphenol, and the like.

Examples of the organic acids include acetic acid, benzoic acid, salicylic acid, p-toluenesulfonic acid, and the like.

The content of the curing accelerator (F) may be 0.01% by mass to 10% by mass, 0.02% by mass to 5% by mass, or 0.05% by mass to 1.5% by mass with respect to a total of 100% by mass of the thermosetting resin.

The thermosetting resin composition of the present embodiment may contain components other than those described above. Examples of other components include antioxidants, leveling agents, and the like.

As a method for manufacturing the thermosetting resin composition of the present embodiment, for example, there are the following methods.

A resin varnish (varnish-like thermosetting resin composition) can be prepared by dissolving, mixing, and stirring each of the components in a solvent. For mixing, various mixers such as an ultrasonic dispersion method, a high-pressure collision type dispersion method, a high-speed rotary dispersion method, a bead mill method, a high-speed shear dispersion method, and a rotation-revolution type dispersion method can be used. From the viewpoint of the effect of the present invention, the thermally conductive particles (D) and the organosiloxane compound (E) may be mixed in advance, and it is preferable to prepare a resin varnish other than the organosiloxane compound (E) and to mix the organosiloxane compound (E) with the resin varnish as an additive.

The solvent is not particularly limited, and examples thereof include acetone, methyl isobutyl ketone, toluene, ethyl acetate, cyclohexane, heptane, cyclohexanone, tetrahydrofuran, dimethylformamide, dimethylacetamide, dimethyl sulfoxide, ethylene glycol, cellosolve-based solvents, carbitol-based solvents, anisole, N-methylpyrrolidone, and the like.

### Resin Sheet

The resin sheet of the present embodiment is obtained by curing the thermosetting resin composition. The specific form of the resin sheet is provided with a carrier base material and a resin layer including the thermosetting resin composition of the present embodiment, which is provided on the carrier base material.

The resin sheet can be obtained by performing solvent removal treatment on a coating film (resin layer) obtained by applying the varnish-like thermosetting resin composition on the carrier base material, for example. It is possible for the solvent content in the resin sheet to be 10% by mass or less with respect to the entire thermosetting resin composition. For example, the solvent removal treatment can be performed under the conditions of 80° C. to 200° C. for 1 minute to 30 minutes.

The resin sheet (resin layer) of the present embodiment is in a B stage state, and the thermosetting resin composition containing no thermally conductive particles (D) serving as a binder preferably includes the following curing behavior.

Specifically, the thermosetting resin composition containing no thermally conductive particles (D) is pre-dried at 115° C. for 12 minutes to prepare a sheet in a B stage state, and a curing torque of the sheet in the B stage state is measured over time at a measurement temperature of 180° C., using a cone plate type rheometer. In a case where Tₘₐₓ is a time required from the start of measurement to the maximum torque, a ratio (T₅₀/Tₘₐₓ) to the time T₅₀ when the value reaches 50% of the maximum torque value from the start of measurement is preferably 0.1 to 1.0, more preferably 0.2 to 0.8, and further more preferably 0.25 to 0.75.

As the cone plate type rheometer, for example, a rheometer “MCR-301” manufactured by Anton Parr GmbH can be used. In addition, the frequency at the time of measurement can be 1 Hz and the swing angle can be 1%.

In a case where the curing behavior (ratio (T₅₀/Tₘₐₓ)) of the thermosetting resin composition containing no filler of the present embodiment is within the above range, it is possible to keep the cycle time during pressing within an appropriate range, and it is possible to suppress occurrence of molding defects such as voids, and thus the productivity of the metal base substrate and the like, which will be described later, is improved.

In addition, in the present embodiment, as the carrier base material, for example, a polymer film or a metal foil can be used. The polymer film is not particularly limited, but examples thereof include polyolefins such as polyethylene and polypropylene, polyesters such as polyethylene terephthalate and polybutylene terephthalate, polycarbonates, release papers such as silicone sheets, thermoplastic resin sheets having heat resistance such as fluorine-based resins and polyimide resins, and the like. The metal foil is not particularly limited, but examples thereof include copper and/or copper-based alloys, aluminum and/or aluminum-based alloys, iron and/or iron-based alloys, silver and/or silver-based alloys, gold and gold-based alloys, zinc and zinc-based alloys, nickel and nickel-based alloys, tin and tin-based alloys, and the like.

The resin substrate of the present embodiment is provided with an insulating layer formed of a cured product of the thermosetting resin composition. It is possible to use this resin substrate as a material for printed substrates for mounting electronic components such as LEDs and power modules.

Metal Base Substrate

A metal base substrate 100 (heat-dissipating resin member) of the present embodiment will be described based on FIG. 1.

FIG. 1 is a schematic cross-sectional view showing an example of the configuration of the metal base substrate 100.

As shown in FIG. 1, it is possible for the metal base substrate 100 to include a metal substrate 101, an insulating layer 102 provided on the metal substrate 101, and a metal layer 103 provided on the insulating layer 102. It is possible for the insulating layer 102 to be formed of one selected from the group consisting of a resin layer formed of the thermosetting resin composition, and a cured product and a laminate of the thermosetting resin composition. Each of these resin layers and laminates may be formed of a thermosetting resin composition in a B stage state (resin sheet) before circuit processing of the metal layer 103 and may be a cured body which is cured and processed therefrom after circuit processing.

The metal layer 103 is provided on the insulating layer 102 and is subjected to circuit processing. Examples of the metal forming the metal layer 103 include one or two or more selected from copper, copper alloy, aluminum, aluminum alloy, nickel, iron, tin, and the like. Among the above, the metal layer 103 is preferably a copper layer or an aluminum layer, and particularly preferably a copper layer. Using copper or aluminum makes it possible to make the circuit processability of the metal layer 103 good. As the metal layer 103, a metal foil available in plate form may be used or a metal foil available in roll form may be used.

In a case where a lower limit value of the thickness of the metal layer 103 is, for example, 0.01 mm or more, and preferably 0.035 mm or more, the metal layer 103 can be applied to applications requiring a high current.

In addition, an upper limit value of the thickness of the metal layer 103 is, for example, 10.0 mm or less, and preferably 5 mm or less. Being such a numerical value or less makes it possible to improve the circuit processability and also to make the substrate as a whole thinner.

The metal substrate 101 has the role of dissipating the heat accumulated in the metal base substrate 100. The metal substrate 101 is not particularly limited as long as it is a heat-dissipating metal substrate, for example, a copper substrate, a copper alloy substrate, an aluminum substrate, or an aluminum alloy substrate, preferably a copper substrate or an aluminum substrate, and more preferably a copper substrate. Using a copper substrate or an aluminum substrate makes it possible to make the heat dissipation of the metal substrate 101 good.

It is possible to appropriately set the thickness of the metal substrate 101 as long as the purpose of the present invention is not impaired.

An upper limit value of the thickness of the metal substrate 101 is, for example, 20.0 mm or less, and preferably 5.0 mm or less. A thickness of the numerical value or less makes it possible to improve the processability of the metal base substrate 100 in outline processing, cut-out processing, and the like.

In addition, a lower limit value of the thickness of the metal substrate 101 is, for example, 0.01 mm or more, and preferably 0.6 mm or more. Using the metal substrate 101 of the numerical value or more makes it possible to improve the heat dissipation of the metal base substrate 100 as a whole.

In the present embodiment, the metal base substrate 100 can be used for various substrate applications, but since it is excellent in thermal conductivity and heat resistance, it can be used as a printed substrate using an LED or a power module.

It is possible for the metal base substrate 100 to have the metal layer 103 which is circuit processed by etching into a pattern, or the like. In the metal base substrate 100, a solder resist not shown in figures may be formed on the outermost layer and the electrode portions for connection may be exposed such that it is possible to mount electronic components thereon by exposure and development.

(Semiconductor Device)

The metal base substrate (heat-dissipating insulating member) 100 of the embodiment can be used for various applications requiring heat-dissipating insulation properties, and can be used, for example, in a semiconductor device.

FIG. 2 is a schematic cross-sectional view showing an example of a semiconductor device using the metal base substrate 100.

A semiconductor element 201 is mounted on the metal layer 103 of the metal base substrate 100 via an adhesive layer 202 (die attach material). The semiconductor element 201 is connected to an electrode portion for connection formed on the metal base substrate 100 via a bonding wire 203, and is mounted on the metal base substrate 100.

The semiconductor element 201 is collectively sealed on the metal base substrate 100 by a encapsulating resin layer 205.

A heat sink 207 is provided on a metal substrate 101 side of the metal base substrate 100 via a thermally conductive layer 206 (thermal interface material (TIM)). The heat sink 207 is formed of a material having excellent thermal conductivity, and examples thereof include metals such as aluminum, iron, and copper.

As described above, the embodiments of the present invention have been described above, but these are examples of the present invention and various configurations other than the above may be adopted within a range not impairing the effect of the present invention.

### EXAMPLES

Hereinafter, the present invention will be described in more detail with reference to examples, but the present invention is not limited thereto.

### Examples 1 to 13 and Comparative Example 1 (Manufacturing of Thermosetting Resin Composition (Varnish-Like))

A varnish-like thermosetting resin composition was obtained by stirring each component and a solvent according to the blending ratios shown in Table 1. In Table 1, the content of the thermally conductive particles is % by volume with respect to the resin component of the thermosetting resin composition containing no thermally conductive filler.

The details of each component in Table 1 are as follows. The unit for the amount of each component in Table 1 is parts by mass.

(Epoxy Resin)

Epoxy resin 1: Epoxy resin represented by the following structural formula, model number “EPICLON HP-4700”, manufactured by DIC Corporation

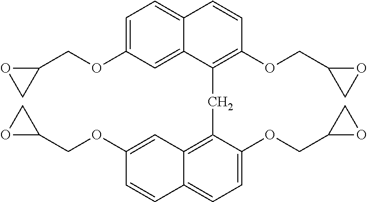 [SMILES: c1cc2ccc(OCC3CO3)c(Cc3c(OCC4CO4)ccc4ccc(OCC5CO5)cc34)c2cc1OCC1CO1]

Epoxy resin 2: Epoxy resin represented by the following structural formula, model number “EPICLON 830”, manufactured by DIC Corporation

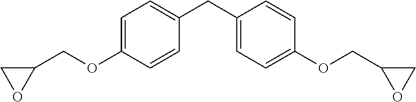 [SMILES: c1cc(OCC2CO2)ccc1Cc1ccc(OCC2CO2)cc1]

(Cyanate Resin)

Cyanate resin 1: Primaset “PT-30”, manufactured by Lonza

(Phenoxy Resin Having a Mesogenic Structure in the Molecule)

Phenoxy resin 1: Phenoxy resin having a mesogenic structure in the molecule obtained by the following synthesis procedure

70.1 parts by mass of an epoxy resin (mesogenic structure, in-house synthesis, 4,4′-dihydroxy biphenyl diglycidyl ether with the following structure), 23.5 parts by mass of bisphenolic compound (mesogenic structure, bifunctional phenol with the following structure, HQPOB manufactured by Ueno Fine Chemicals Industry Ltd.), 0.06 parts by mass of triphenylphosphine (TPP) , and 6.3 parts by mass of solvent (methyl ethyl ketone) were dropped into a reactor. A reaction was then carried out at a temperature of 150° C. while removing the solvent. The reaction was stopped after confirming that the desired molecular weight was achieved by GPC. Due to this, a phenoxy resin 1 with a molecular weight of 4,500 was obtained.

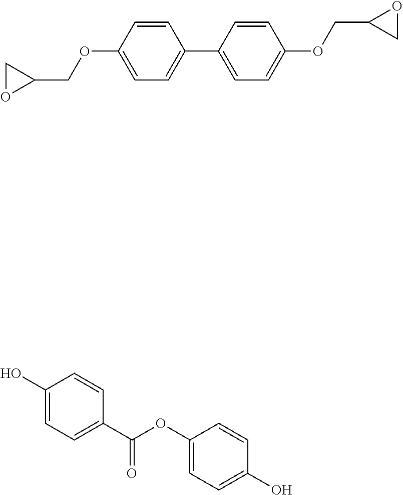 [SMILES: c1cc(-c2ccc(OCC3CO3)cc2)ccc1OCC1CO1 ; O=C(Oc1ccc(O)cc1)c1ccc(O)cc1]

Phenoxy resin 2: Phenoxy resin having a mesogenic structure in the molecule obtained by the following synthesis procedure.

77.1 parts by mass of epoxy resin (mesogenic structure, in-house synthesis, 4,4′-dihydroxy biphenyl diglycidyl ether) with the following structure, 18.0 parts by mass of bisphenolic compound (mesogenic structure, bifunctional phenol with the following structure, 2,7-DHN, manufactured by Yamada Chemical Co., Ltd.), 0.08 parts by mass of triphenylphosphine (TPP), and 4.8 parts by mass of solvent (methyl ethyl ketone) were dropped into the reactor. A reaction was then carried out at a temperature of 150° C. while removing the solvent. The reaction was stopped after confirming that the desired molecular weight was achieved by GPC. Due to this, a phenoxy resin 2) with a molecular weight of 5,200 was obtained.

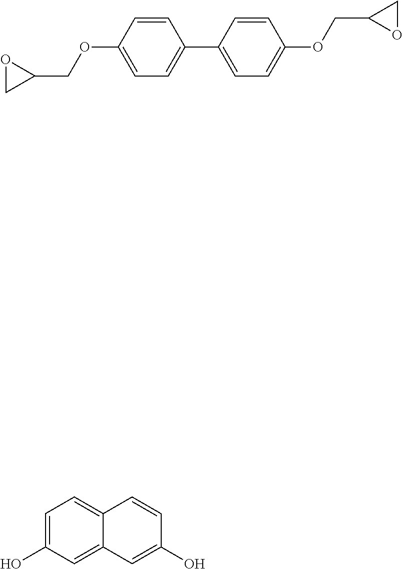 [SMILES: c1cc(-c2ccc(OCC3CO3)cc2)ccc1OCC1CO1 ; Oc1ccc2ccc(O)cc2c1]

Phenoxy resin 3: Phenoxy resin having a mesogenic structure in the molecule obtained by the following synthesis procedure.

72.8 parts by mass of an epoxy resin (mesogenic structure, YX-4000, manufactured by Mitsubishi Chemical Corporation), 21.4 parts by mass of bisphenolic compound (mesogenic structure, bifunctional phenol with the following structure, in-house synthesis, 4,4′-dihydroxy chalcone), 0.07 parts by mass of triphenylphosphine (TPP), and 5.7 parts by mass of solvent (methyl ethyl ketone) were dropped into the reactor. A reaction was then carried out at a temperature of 120° C. to 150° C. while removing the solvent. The reaction was stopped after confirming that the desired molecular weight was achieved by GPC. Due to this, a phenoxy resin 3 with a molecular weight of 4,300 was obtained.

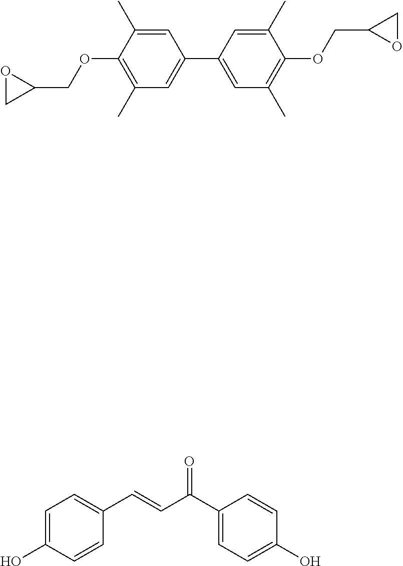 [SMILES: Cc1cc(-c2cc(C)c(OCC3CO3)c(C)c2)cc(C)c1OCC1CO1 ; O=C(/C=C/c1ccc(O)cc1)c1ccc(O)cc1]

Phenoxy resin 4: Phenoxy resin having a mesogenic structure in the molecule obtained by the following synthesis procedure.

75.5 parts by mass of an epoxy resin (mesogenic structure, HP-4032D, manufactured by DIC Corporation) with the following structure, 19.3 parts by mass of bisphenolic compound (mesogenic structure, bifunctional phenol with the following structure, 2,7-DHN, manufactured by Yamada Chemical Co., Ltd.), 0.09 parts by mass of triphenylphosphine (TPP), and 5.1 parts by mass of solvent (methyl ethyl ketone) were dropped into the reactor. A reaction was then carried out at a temperature of 150° C. while removing the solvent. The reaction was stopped after confirming that the desired molecular weight was achieved by GPC. Due to this, a phenoxy resin 4 with a molecular weight of 5,400 was obtained.

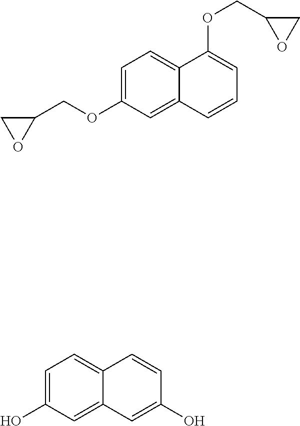 [SMILES: c1cc(OCC2CO2)c2ccc(OCC3CO3)cc2c1 ; Oc1ccc2ccc(O)cc2c1]

(Curing Accelerator)

Curing accelerator 1: Novolac type phenolic compound (PR-51470, manufactured by Sumitomo Bakelite Co., Ltd.)

(Organosiloxane Compound)

Organosiloxane 1: 3-glycidoxypropyltriethoxysilane

Organosiloxane 2: 3-glycidoxypropyltrimethoxysilane

Organosiloxane 3: 3-mercaptopropyltriethoxysilane

Organosiloxane 4: 3-isocyanatepropyltriethoxysilane

Organosiloxane 5: 3-aminopropyltriethoxysilane

Organosiloxane 6: Glycydoxyoctyltrimexysilane

Organosiloxane 7: Decyltriethoxysilane

Organosiloxane 8: 2,2-dimethoxy-1-phenyl-1-aza-2-silacyclopentane

(Thermally Conductive Particles)

Thermally conductive particles 1: Cohesive boron nitride, (HP40, manufactured by Mizushima Ferroalloy Co., Ltd.)

### Measurement of Curing Behavior of Thermosetting Composition in B Stage State

A thermosetting resin composition containing no thermally conductive particles was pre-dried at 115° C. for 12 minutes to prepare a sheet in a B stage state, and a curing torque of the sheet in a B stage state was measured over time at a measurement temperature of 180° C. using a cone-plate viscometer (Rheometer MCR-301 manufactured by Anton Parr GmbH). From the measurement results, in a case where a time of a maximum curing torque value was denoted as Tₘₐₓ, and the time when the torque value reached 50% of the maximum torque value from the start of measurement is denoted as T₅₀, T₅₀/Tₘₐₓ was calculated.

### Measurement of Physical Properties of Resin Molded Body of Thermosetting Resin Composition

(Thermal Conductivity)

Preparation of Resin Molded Body

The obtained thermosetting resin composition containing a thermally conductive filler was used, sandwiched and set between 0.018 μm of copper foils, and compression molding was performed at 10 MPa at 180° C. for 90 minutes to obtain a resin molded body (thermal conductivity measurement sample 1). A thermal diffusivity measurement sample having a diameter of 10 mm was cut out from the obtained molded body and used for the thermal diffusivity measurement.

Specific Gravity of Resin Molded Body

Measurement of the specific gravity was performed in accordance with JIS K 6911 (general test method for thermosetting plastics). As a test piece, a piece cut out from the resin molded body into a length of 2 cm and a width of 2 cm was used. The unit of specific gravity (SP) is g/cm^{3.}

Specific Heat of Resin Molded Body

A specific heat (Cp) of the obtained resin molded body was measured by the DSC method.

Measurement of Thermal Conductivity of Resin Molded Body

A test piece was cut out from the obtained resin molded body to a diameter of 10 mm for measurement in a thickness direction. Next, the thermal diffusivity coefficient (α) in the thickness direction of the plate-shaped test piece was measured by an unsteady method using the Xe flash analyzer TD-1RTV manufactured by ULVAC. The measurement was carried out under the condition of 25° C. in the atmospheric atmosphere.

For the resin molded body, the thermal conductivity was calculated from the obtained measurement values of the obtained thermal diffusivity coefficient (α), specific heat (Cp), and specific gravity (SP) based on the following formula.

Thermal conductivity [W/m·K]=α[m²/s]×Cp [J/kg·K]×Sp [g/cm³]

In Table 1, the thermal conductivity of the resin molded body was defined as “thermal conductivity”.

(Volume Resistivity)

The measurement was carried out in accordance with JIS C 2139.

Specifically, the cured product for measurement, which was processed to an appropriate size, stood in an oven at 30° C. and the volume resistivity was measured upon reaching a targeted temperature (that is, 30° C.).

(Moisture Absorption Rate)

The copper foil was removed from the obtained resin molded body by etching, and the moisture absorption rate (%) was calculated from the weight change before and after the treatment when the copper foil was left under a condition of 30° C./90% RH for 48 hours.

(Insulation Durability)

Specifically, a resin molded body having a 25 mmφ ring electrode on one surface and a copper foil on the other surface was prepared and stood under a condition of 85° C./85% RH with the ring electrode side as an anode and the copper foil side as a cathode, and the time required for conduction at a time of application of a DC voltage of 2 kV was measured. Evaluation was performed according to the following criteria.

(Evaluation Criteria)

A: No conduction even at 100 hr or more

B: Conduction in less than 100 hr.

TABLE 1

| | | Example | | | | | | | |
|---|---|---|---|---|---|---|---|---|---|
| | Unit | 1 | 2 | 3 | 4 | 5 | 6 | 7 | 8 |
| Epoxy resin 1 | Parts by mass | 15 | 15 | 15 | 15 | 15 | 15 | 15 | 15 |
| Epoxy resin 2 | | 13 | 13 | 13 | 13 | 13 | 13 | 13 | 13 |
| Cyanate resin 1 | | 45 | 45 | 45 | 45 | 45 | 45 | 45 | 45 |
| Phenoxy resin 1 | | 26 | 26 | 26 | 26 | | | | 26 |
| Phenoxy resin 2 | | | | | | 26 | | | |
| Phenoxy resin 3 | | | | | | | 26 | | |
| Phenoxy resin 4 | | | | | | | | 26 | |
| Curing accelerator 1 | | 1 | 1 | 1 | 1 | 1 | 1 | 1 | 1 |
| Sum of resin component | | 100 | 100 | 100 | 100 | 100 | 100 | 100 | 100 |
| Organosiloxane 1 | Parts by mass | 0.1 | 0.3 | 0.5 | | | | | |
| Organosiloxane 2 | | | | | 0.5 | 0.5 | 0.5 | 0.5 | |
| Organosiloxane 3 | | | | | | | | | 0.5 |
| Organosiloxane 4 | | | | | | | | | |
| Organosiloxane 5 | | | | | | | | | |
| Organosiloxane 6 | | | | | | | | | |
| Organosiloxane 7 | | | | | | | | | |
| Organosiloxane 8 | | | | | | | | | |
| Thermally conductive | Parts by mass | 300 | 300 | 300 | 300 | 300 | 300 | 300 | 300 |
| particles 1 | phr | 300 | 300 | 300 | 300 | 300 | 300 | 300 | 300 |
| Curing behavior of B | — | | | 0.42 | | | | 0.36 | |
| stage curing | | | | | | | | | |
| composition (T₅₀/Tₘₐₓ) | | | | | | | | | |
| Glass transition | ° C. | 232 | 233 | 231 | 230 | 235 | 236 | 241 | 228 |
| temperature Tg | | | | | | | | | |
| Thermal conductivity | W/(m · K) | 19.2 | 19.1 | 18.6 | 18.6 | 19.2 | 18.5 | 18.4 | 23.2 |
| Volume resistivity | Ωcm | IE+16 | 1E+16 | IE+16 | IE+16 | 1E+16 | 1E+16 | IE+16 | 1E+16 |
| Moisture absorption | % | 0.37 | 0.32 | 0.29 | 0.29 | 0.28 | 0.29 | 0.38 | 0.33 |
| rate | | | | | | | | | |
| Insulation durability | 2 kV, | A | A | A | A | A | A | A | A |
| | DC > 100 hr | | | | | | | | |

| | | | | | | Comparative |
|---|---|---|---|---|---|---|
| | Example | | | | | Example |
| | 9 | 10 | 11 | 12 | 13 | 1 |
| Epoxy resin 1 | 15 | 15 | 15 | 15 | 15 | 15 |
| Epoxy resin 2 | 13 | 13 | 13 | 13 | 13 | 13 |
| Cyanate resin 1 | 45 | 45 | 45 | 45 | 45 | 45 |
| Phenoxy resin 1 | 26 | 26 | 26 | 26 | 26 | 26 |
| Phenoxy resin 2 | | | | | | |
| Phenoxy resin 3 | | | | | | |
| Phenoxy resin 4 | | | | | | |
| Curing accelerator 1 | 1 | 1 | 1 | 1 | 1 | 1 |
| Sum of resin component | 100 | 100 | 100 | 100 | 100 | 100 |
| Organosiloxane 1 | | | | | | |
| Organosiloxane 2 | | | | | | |
| Organosiloxane 3 | | | | | | |
| Organosiloxane 4 | 0.5 | | | | | |
| Organosiloxane 5 | | 0.5 | | | | |
| Organosiloxane 6 | | | 0.5 | | | |
| Organosiloxane 7 | | | | 0.5 | | |
| Organosiloxane 8 | | | | | 0.5 | |
| Thermally conductive | 300 | 300 | 300 | 300 | 300 | 300 |
| particles 1 | 300 | 300 | 300 | 300 | 300 | 300 |
| Curing behavior of B | | | | | | 0.37 |
| stage curing | | | | | | |
| composition (T₅₀/Tₘₐₓ) | | | | | | |
| Glass transition | 225 | 232 | 229 | 231 | 228 | 232 |
| temperature Tg | | | | | | |
| Thermal conductivity | 22.6 | 24.9 | 22.5 | 24.1 | 18.8 | 17.8 |
| Volume resistivity | 1E+16 | 1E+16 | 1E+16 | IE+16 | 1E+16 | 1E+16 |
| Moisture absorption | 0.38 | 0.38 | 0.39 | 0.34 | 0.29 | 0.52 |
| rate | | | | | | |
| Insulation durability | A | A | A | A | A | B |

This application claims priority based on Japanese Application JP 2019-222223 filed on Dec. 9, 2019, the entire disclosure of which is hereby incorporated herein.

### REFERENCE SIGNS LIST

100: Metal base substrate

101: Metal substrate

102: Insulating layer

103: Metal layer

200: Semiconductor device

201: Semiconductor element

202: Adhesive layer

203: Bonding wire

205: Encapsulating resin layer

206: thermally conductive layer

207: heat sink

What is claim is:

1. A thermosetting resin composition constituting at least a part of a heat-dissipating insulating member interposed between a heat-generating body and a heat-dissipating body, the thermosetting resin composition comprising:
(A) an epoxy resin;
(B) a thermosetting resin (excluding epoxy resin (A));
(C) a phenoxy resin containing a mesogenic structure in a molecule;
(D) thermally conductive particles; and
(E) an organosiloxane compound.

2. The thermosetting resin composition according to claim 1,
wherein thermal conductivity of the heat-dissipating insulating member is 12 W/m·K or more.

3. The thermosetting resin composition according to claim 1,
wherein the thermally conductive particles (D) contain at least one selected from silica, alumina, aluminum nitride, boron nitride, silicon nitride, silicon carbide, and magnesium oxide.

4. The thermosetting resin composition according to claim 1,
wherein the thermally conductive particles (D) contain the boron nitride in an amount of 60% by mass or more.

5. The thermosetting resin composition according to claim 3,
wherein the thermally conductive particles (D) contain the boron nitride, and the boron nitride includes monodispersed particles, granular particles, aggregated particles, or a mixture of these particles of scaly boron nitride.

6. The thermosetting resin composition according to claim 1,
wherein the organosiloxane compound (E) contains at least one group selected from an epoxy group, a glycidyl ether group, an amino group, an isocyanate group, a phenyl group, a carboxyl group, a hydroxyl group, an alkyl group, a vinyl group, a mercapto group, and an azasilacyclopentyl group.

7. The thermosetting resin composition according to claim 1,
wherein the organosiloxane compound (E) is contained in an amount of 0.01 to 1 part by mass with respect to 100 parts by mass of the thermally conductive particles (D).

8. The thermosetting resin composition according to claim 1,
wherein the phenoxy resin (C) contains a structural unit derived from a phenolic compound and a structural unit derived from an epoxy compound.

9. The thermosetting resin composition according to claim 1,
wherein the phenoxy resin (C) contains the mesogenic structure selected from a biphenyl skeleton, a phenylbenzoate skeleton, an azobenzene skeleton, a stilbene skeleton, a naphthalene skeleton, an anthracene skeleton, a chalcone skeleton, and a phenanthrene skeleton.

10. The thermosetting resin composition according to claim 1,
wherein the thermosetting resin (B) contains at least one selected from a cyanate resin, a maleimide resin, a phenolic resin, and a benzoxazine resin.

11. The thermosetting resin composition according to claim 1,
wherein the epoxy resin (A) contains an epoxy resin having a mesogenic structure.

12. The thermosetting resin composition according to claim 1, further comprising: a curing accelerator (F).

13. The thermosetting resin composition according to claim 1,
wherein a ratio (T₅₀/Tₘₐₓ) calculated under the following conditions is 0.1 to 1.0, (Conditions)
a thermosetting resin composition containing no thermally conductive particles (D) is pre-dried at 115° C. for 12 minutes to prepare a sheet in a B stage state, and a curing torque of the sheet in the B stage state is measured over time at a measurement temperature of 180° C. using a cone-plate viscometer Rheometer, in a case where a time of a maximum curing torque value is denoted as Tₘₐₓ, and a time when the torque value reaches 50% of the maximum torque value from the start of measurement is denoted as T₅₀, the ratio (T₅₀/Tₘₐₓ) is calculated.

14. A resin sheet comprising:
the thermosetting resin composition according to claim 1.

15. The resin sheet according to claim 14, which is in the B stage state.

16. A metal base substrate comprising:
a metal substrate;
an insulating layer obtained by curing the resin sheet according to claim 14; and
a metal layer in this order.
